(19) United States
(12) Patent Application Publication
(10) Pub. No.: US 2018/0113291 A1
(43) Pub. Date: Apr. 26, 2018

(54) LASER MICROSCOPE AND LASER MICROSCOPE SYSTEM

(71) Applicant: OLYMPUS CORPORATION, Tokyo (JP)

(72) Inventor: Hirokazu KUBO, Tokyo (JP)

(73) Assignee: OLYMPUS CORPORATION, Tokyo (JP)

(21) Appl. No.: 15/729,016

(22) Filed: Oct. 10, 2017

(30) Foreign Application Priority Data
Oct. 25, 2016 (JP) 2016-208689

(51) Int. Cl. G02B 21/00; G01J 1/44; H01L 31/09; H01L 31/024; H01L 31/0352

(52) U.S. Cl. CPC G02B 21/0064; G02B 21/008; G01J 1/44; H01L 31/09; G02B 27/141; H01L 31/035227; G01J 2001/442; G02B 21/0048; H01L 31/024

(57) ABSTRACT

Provided is a laser microscope that includes a beam-scanning unit that scans a sample with a laser beam emitted from a laser light source; two or more photodetectors each formed of a superconducting nanowire single photon detector that detects a beam returning from the sample as a result of the scanning of the laser beam by the beam-scanning unit; and one cryocooler that cools the photodetectors. The photodetectors respectively detect beams that have passed through different channels.

### CROSS-REFERENCE TO RELATED APPLICATIONS

This application claims the benefit of Japanese Patent Application No. 2016-208689, the contents of which is incorporated herein by reference.

### TECHNICAL FIELD

The present invention relates to a laser microscope and a laser microscope system.

### BACKGROUND ART

In the related art there is a known superconducting nanowire single photon detector (SSPD) serving as a high-quantum-efficiency, low-dark-noise photodetector for a microscope (for example, refer to NPL 1).

### CITATION LIST

### Non Patent Literature

### {NPL 1}

OPTICS EXPRESS 32633, vol. 23, No. 25, 14 Dec. 2015, DOI: 10.1364/OE.23.032633.

### SUMMARY OF INVENTION

An aspect of the present invention provides a laser microscope that includes a beam-scanning unit that scans a sample with a laser beam emitted from a laser light source; two or more photodetectors each formed of a superconducting nanowire single photon detector that detects a beam returning from the sample as a result of the scanning of the laser beam by the beam-scanning unit; and one cryocooler that cools the photodetectors, in which the photodetectors respectively detect beams that have passed through different channels.

Another aspect of the present invention provides a laser microscope system that includes two or more laser microscopes each equipped with a beam-scanning unit that scans a sample with a laser beam emitted from a laser light source, and at least one photodetector formed of a superconducting nanowire single photon detector that detects a beam returning from the sample as a result of the scanning of the laser beam by the beam-scanning unit; and one cryocooler that cools the photodetectors of the laser microscopes.

### BRIEF DESCRIPTION OF DRAWINGS

FIG. 1 is an overall view of a laser microscope according to one embodiment of the present invention.

FIG. 2 is a schematic diagram illustrating the structure of a microscope body of the laser microscope illustrated in FIG. 1,

FIG. 3 is a schematic diagram illustrating a spectral optical system and a cryocooler of the laser microscope illustrated in FIG. 1.

FIG. 4 is an overall view of a laser microscope system according to another embodiment of the present invention.

### DESCRIPTION OF EMBODIMENTS

A laser microscope 1 according to one embodiment of the present invention will now be described with reference to the drawings.

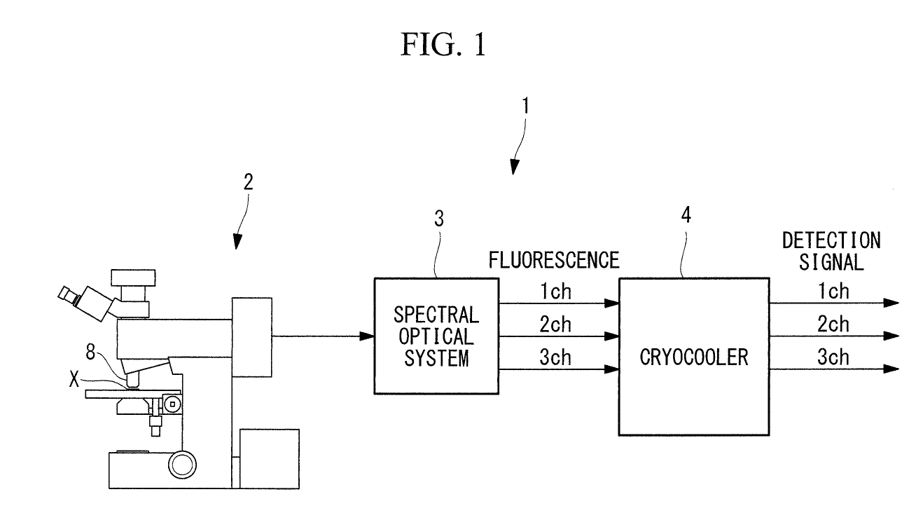

As illustrated in FIG. 1, the laser microscope 1 of this embodiment includes a microscope body 2, a spectral optical system 3 connected to the microscope body 2, a cryocooler 4, and optical fibers (beam-guiding members) 5 that connect the spectral optical system 3 and the cryocooler 4.

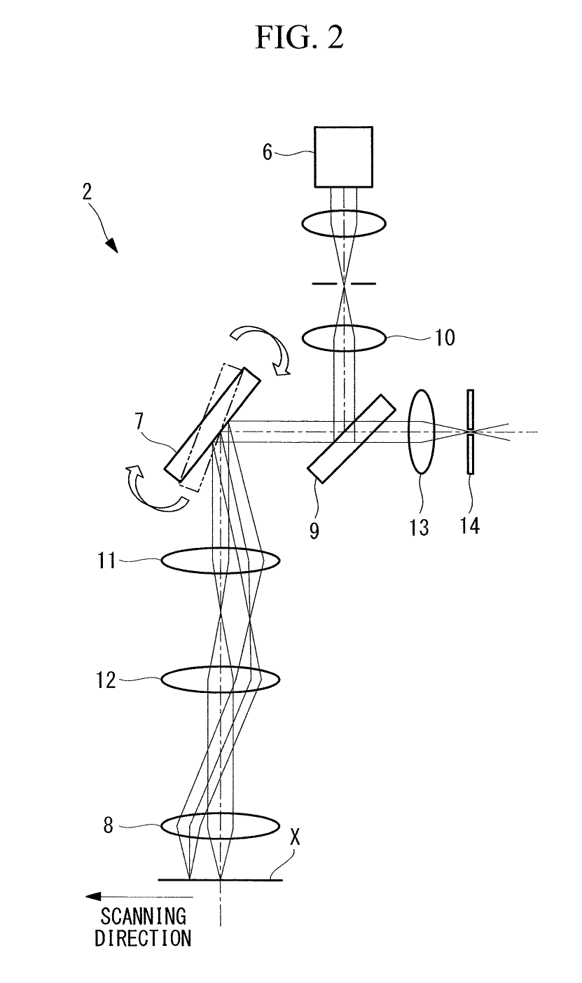

As illustrated in FIG. 2, the microscope body 2 includes a galvanometer mirror (beam-scanning unit) 7 that two-dimensionally scans a laser beam from a laser light source 6, an objective lens 8 that focuses the laser beam scanned by the galvanometer mirror 7 on a sample X while collecting fluorescence generated in the sample X, and a dichroic mirror 9 that splits, from the beam path of the laser beam, the fluorescence collected by the objective lens 8 and returning via the galvanometer mirror 7. In the drawing, reference sign 10 denotes a collimating lens that converts the laser beam from the laser light source 6 into a substantially parallel beam, reference signs 11 and 12 respectively denote a pupil projector lens and an imaging lens that relay the laser beam and the fluorescence, reference sign 13 denotes a focusing lens, and reference numeral 14 denotes a confocal pinhole.

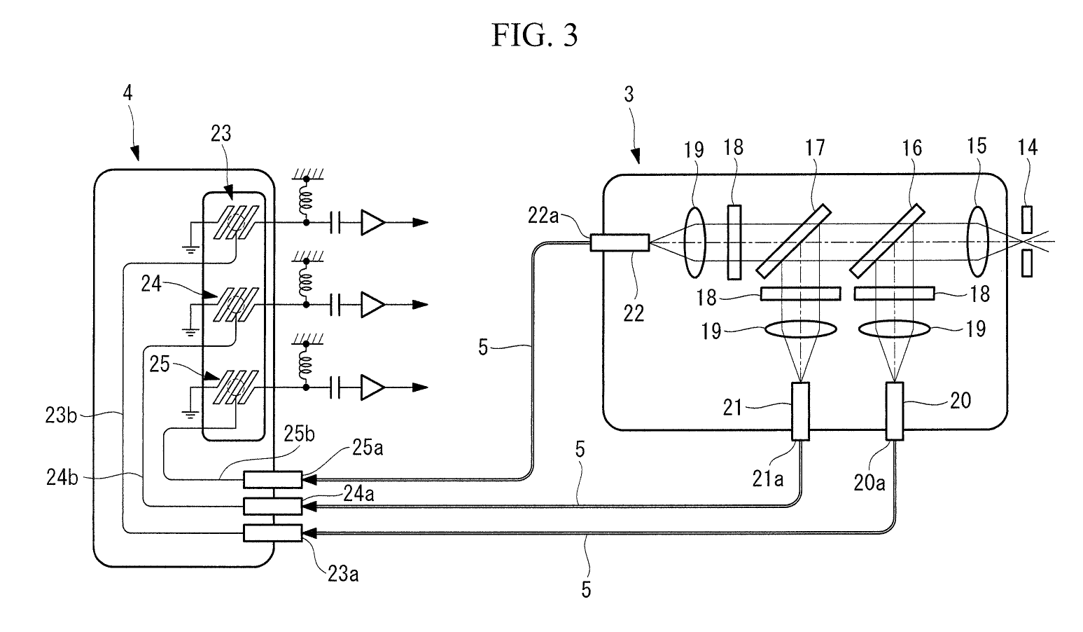

As illustrated in FIG. 3, the spectral optical system 3 includes a collimating lens 15 that converts fluorescence that has passed through the confocal pinhole 14 into a substantially parallel beam, two dichroic mirrors 16 and 17 that split the fluorescence, which has been converted by the collimating lens 15 into a substantially parallel beam, according to the wavelength, a barrier filter 18 that blocks the laser beam contained in the fluorescence, and a focusing lens 19 that focuses the fluorescence that has passed through the barrier filter 18. A portion of the fluorescence is split by being polarized by the first dichroic mirror 16, and a portion of the rest of the fluorescence that has passed through the dichroic mirror 16 is split into two by the second dichroic mirror 17 so that fluorescences having different wavelength ranges are emitted from emission ports 20a, 21a, and 22a of three channels 20, 21, and 22.

As illustrated in FIG. 3, the cryocooler 4 has three photodetectors 23, 24, and 25 inside and is configured to cool the photodetectors 23, 24, and 25 to an ultra-low temperature state so that a superconducting state is maintained. The photodetectors 23, 24, and 25 are each formed of an SSPD and are configured so that the fluorescences coming into beam-capturing ports (channel) 23a, 24a, and 25a are guided via optical fibers 23b, 24b, and 25b and so that a voltage signal corresponding to the number of photons in each in-coming beam is externally output. The photodetectors 23, 24, and 25 preferably have sensitivity peaks corresponding to the wavelengths of beams from the emission ports 20a, 21a, and 22a.

The optical fibers 5 are multi-mode fibers that respectively connect the three emission ports 20a, 21a, and 22a of the spectral optical system 3 to the three beam-capturing ports 23a, 24a, and 25a of the cryocooler 4.

According to the laser microscope 1 of this embodiment configured as such, the laser beam emitted from the laser light source 6 is converted into a substantially parallel beam by the collimating lens 10, is deflected by the dichroic mirror 9, and enters the galvanometer mirror 7. The laser beam two-dimensionally scanned by the operation of the galvanometer mirror 7 passes through the pupil projector lens 11 and the imaging lens 12 and is focused on the sample X by the objective lens 8.

In the sample X, a fluorescent substance at the scan position of the laser beam is excited and fluorescence is generated. The fluorescence generated is collected by the objective lens 8, and passes through the dichroic mirror 9 on the way to return via the imaging lens 12, the pupil projector lens 11, and the galvanometer mirror 7; as a result, the fluorescence is split from the beam path of the laser beam and is focused by the focusing lens 13, and a portion of the fluorescence that has passed through the confocal pinhole 14 enters the spectral optical system 3.

The fluorescence that has entered the spectral optical system 3 is converted into a substantially parallel beam by the collimating lens 15 and is split into two beam paths by the dichroic mirror 16 according to the wavelength, and one of the split portions is further split into two beam paths by the dichroic mirror 17 according to the wavelength. As such, the fluorescence is split into three beam paths, each split portion is focused by the focusing lens 19 after the laser beam contained in the fluorescence is removed by the barrier filter 18, and the resulting fluorescences are emitted from the three emission ports 20a, 21a, and 22a of the three channels 20, 21, and 22.

Since the emission ports 20a, 21a, and 22a of the three channels 20, 21, and 22 are respectively connected to the optical fibers 5, the fluorescences are guided via the optical fibers 5 and respectively enter the three beam-capturing ports 23a, 24a, and 25a of the cryocooler 4.

In the cryocooler 4, the fluorescences from the three channels 20, 21, and 22 are guided from beam-capturing ports 23a, 24a, and 25a into different photodetectors 23, 24, and 25 via optical fibers 23b, 24b, and 25b, and are detected by the photodetectors 23, 24, and 25. As a result, detection signals of three channels 20, 21, and 22 are obtained.

In this case, according to the laser microscope 1 of this embodiment, because the fluorescences of the three channels 20, 21, and 22 output from the microscope body 2 are detected by the three photodetectors 23, 24, and 25 cooled to an ultra-low temperature and maintained in a superconducting state by the cryocooler 4, the fluorescences can be detected at high quantum efficiency and low dark noise. This offers an advantage in that, since the photodetectors 23, 24, and 25 for the three channels 20, 21, and 22 are cooled by one cryocooler 4, the space needed for the cryocooler 4 can be significantly reduced and the cost for the cryocooler 4 can be significantly reduced compared to when the photodetectors 23, 24, and 25 are cooled by separate cryocoolers.

Moreover, there is another advantage in that, since the photodetectors 23, 24, and 25 are cooled by one cryocooler 4, variations in cooling temperature among the channels 20, 21, and 22 are eliminated, and the performance of the photodetectors 23, 24, and 25 can be stabilized among the channels 20, 21, and 22.

Another advantage is that, since the photodetectors 23, 24, and 25 have sensitivity peaks corresponding to the wavelengths of the beams from the emission ports 20a, 21a, and 22a, beams of all wavelengths can be detected at high sensitivity by setting the sensitivity peak according to the wavelength of the beam to be detected.

The optical fibers 5 are used to connect the emission ports 20a, 21a, and 22a of the spectral optical system 3 to the beam-capturing ports 23a, 24a, and 25a of the cryocooler 4 in this embodiment; alternatively, glass rods may be used to form connections, or mirrors may be used to guide fluorescences to the beam-capturing ports 23a, 24a, and 25a via air beam paths. Although an example in which the spectral optical system 3 has three emission ports 20a, 21a, and 22a in three channels 20, 21, and 22 is described above, the spectral optical system 3 may have any number of channels greater than 1.

Next, a laser microscope system 100 according to another embodiment of the present invention is described with reference to the drawings.

In the description of this embodiment, the parts common to those of the laser microscope 1 are denoted by the same reference numerals, and the descriptions therefor are not repeated.

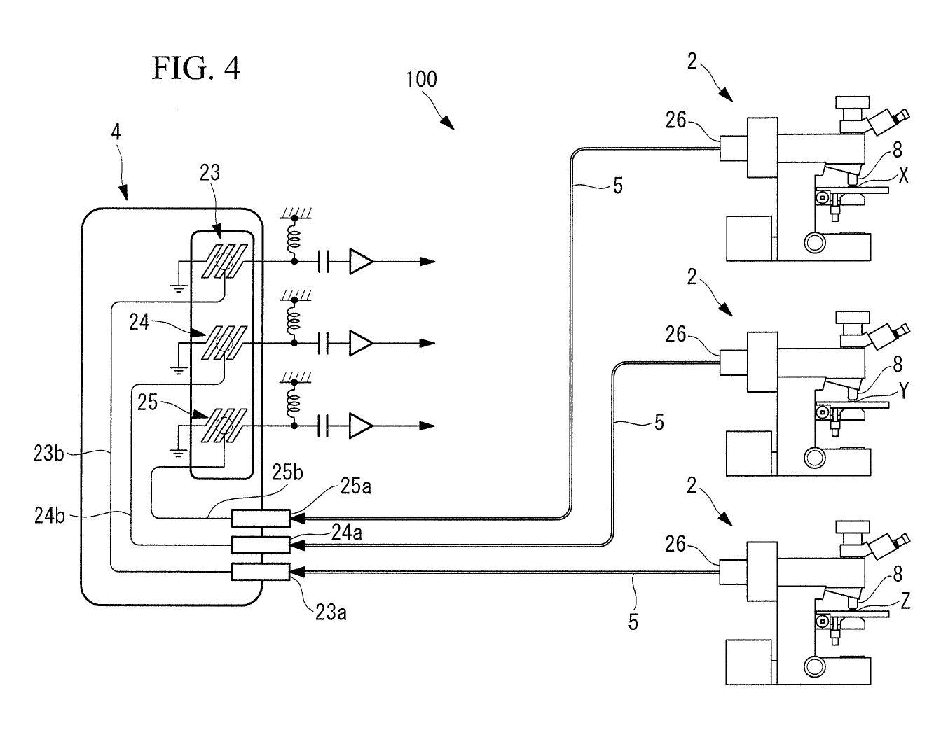

As illustrated in FIG. 4, the laser microscope system 100 of this embodiment includes multiple microscope bodies (laser microscopes) 2, one cryocooler 4, and optical fibers 5 that connect emission ports 26 of the microscope bodies 2 to beam-capturing ports 23a, 24a, and 25a of the cryocooler 4.

Each of the emission ports 26 of the microscope bodies 2 is provided downstream of a focusing lens 19 provided downstream of a confocal pinhole 14. The fluorescence focused by the focusing lens 19 enters the inlet end of the optical fiber 5 connected to the emission port 26 and is guided into the cryocooler 4.

According to the laser microscope system 100 of this embodiment, fluorescences from separate samples, X, Y, and Z, detected with the microscope bodies 2 can be detected by photodetectors 23, 24, and 25 installed in one cryocooler 4, and there is an advantage in that the space and cost can be reduced by sharing the cryocooler 4. Moreover, since the photodetectors 23, 24, and 25 are cooled by one cryocooler 4, variations in cooling temperatures among the photodetectors 23, 24, and 25 connected to the microscope bodies 2 can be eliminated, and the performance of the photodetectors 23, 24, and 25 can be stabilized.

Note that, in this embodiment, the emission ends of the optical fibers 5 at the beam-capturing ports 23a, 24a, and 25a of the cryocooler 4 can be made removable and replaceable. Since there is a limit to the number of the photodetectors 23, 24, and 25 that can be installed in the cryocooler 4, the emission ends of the optical fibers 5 can be replaced in detecting fluorescences detected by more microscopes than there are photodetectors 23, 24, and 25.

The optical fibers 5 are connected to the emission ports 26 of the microscope bodies 2 in this embodiment; alternatively, the same spectral optical system 3 as that of the laser microscope 1 of the above-described embodiment may be provided, and the optical fibers 5 may be connected to the channels 20, 21, and 22 of the spectral optical system 3. In this manner, the fluorescences emitted from each microscope body 2 and split into beams having different wavelengths by the spectral optical system 3 can be detected by the photodetectors 23, 24, and 25 installed in one cryocooler 4.

From the above-described embodiment, the following invention is derived.

An aspect of the present invention provides a laser microscope that includes a beam-scanning unit that scans a sample with a laser beam emitted from a laser light source; two or more photodetectors each formed of a superconducting nanowire single photon detector that detects a beam returning from the sample as a result of the scanning of the laser beam by the beam-scanning unit; and one cryocooler that cools the photodetectors, in which the photodetectors respectively detect beams that have passed through different channels.

In the aspect described above, when the sample is optically scanned with a laser beam emitted from the laser light source by operation of the beam-scanning unit, the beam returning from each scan position is detected with the photodetector. Thus, by associating the information of the scan positions with the amount of light detected with the photodetector, an image of the sample can be generated. In this case, because multiple photodetectors installed in the laser microscope are cooled by one cryocooler so as to maintain the SSPDs constituting the photodetectors in a superconducting state, SSPDs operate normally, and observation can be conducted at high quantum efficiency and low dark noise. Compared to when separate cryocoolers are used to freeze multiple photodetectors that detect beams that have passed through different channels, the cryocooler is shared by the multiple photodetectors, and thus the space and cost needed for the cryocoolers for each channel can be reduced. Thus, the increase in size and cost of the equipment can be suppressed.

In the aspect described above, the channels may cause beams having different wavelengths to enter the photodetectors.

In this manner, the multiple photodetectors for detecting the beams having different wavelengths can be cooled with one cryocooler, the SSPDs constituting the photodetectors can be maintained in a superconducting state so as to operate normally, and observation can be conducted at high quantum efficiency and low dark noise.

In the aspect described above, the laser microscope may further include a spectral optical system that disperses a beam returning from the sample into beams having different wavelengths, in which the beams dispersed by the spectral optical system are detected by the photodetectors via the channels.

In this manner, the beam returning from the sample is dispersed into multiple beams having multiple wavelengths by the spectral optical system, and the multiple beams having multiple wavelengths can be observed at high quantum efficiency and low dark noise by using the photodetectors formed of SSPDs cooled by one cryocooler.

In the aspect described above, the photodetectors may respectively have sensitivity peaks corresponding to the wavelengths of the beams.

When the sensitivity peaks of the photodetectors formed of SSPDs are set to correspond to the wavelengths of the beams to be detected, the beams of all wavelengths can be detected at high sensitivity.

In the aspect described above, the channels may be connected to the photodetectors via beam-guiding members

In this manner, the beams that have passed through different channels are detected by the multiple photodetectors after the beams are guided by the beam-guiding members. Since the photodetectors are disposed inside the cryocooler, the beams can be guided by the beam-guiding members and can be detected without fail.

In the aspect described above, the beam-guiding members may be configured to be connectable to different ones of the channels.

In this manner, by switching the channels to which the beam-guiding members are connected, a beam that has passed through a different channel can be detected with a different photodetector. This is effective when there are fewer photodetectors than there are channels.

Another aspect of the present invention provides a laser microscope system that includes two or more laser microscopes each equipped with a beam-scanning unit that scans a sample with a laser beam emitted from a laser light source, and at least one photodetector formed of a superconducting nanowire single photon detector that detects a beam returning from the sample as a result of the scanning of the laser beam by the beam-scanning unit; and one cryocooler that cools the photodetectors of the laser microscopes.

### REFERENCE SIGNS LIST

1 laser microscope
2 microscope body (laser microscope)
3 spectral optical system
4 cryocooler
5 optical fiber (beam-guiding member)
6 laser light source
7 galvanometer mirror (beam-scanning unit)
23, 24, 25 photodetector
23a, 24a, 25a beam-capturing port (channel)
100 laser microscope system
X, Y, Z sample

1. A laser microscope comprising:
a beam-scanning unit that scans a sample with a laser beam emitted from a laser light source;
two or more photodetectors each formed of a superconducting nanowire single photon detector that detects a beam returning from the sample as a result of the scanning of the laser beam by the beam-scanning unit; and
one cryocooler that cools the photodetectors,
wherein the photodetectors respectively detect beams that have passed through different channels.

2. The laser microscope according to claim 1, wherein the channels cause beams having different wavelengths to enter the photodetectors.

3. The laser microscope according to claim 2, further comprising:
a spectral optical system that disperses a beam returning from the sample into beams having different wavelengths,
wherein the beams dispersed by the spectral optical system are detected by the photodetectors via the channels.

4. The laser microscope according to claim 2, wherein the photodetectors respectively have sensitivity peaks corresponding to the wavelengths of the beams.

5. The laser microscope according to claim 1, wherein the channels are connected to the photodetectors via beam-guiding members.

6. The laser microscope according to claim 5, wherein the beam-guiding members are configured to be connectable to different ones of the channels.

7. A laser microscope system comprising:
two or more laser microscopes each equipped with a beam-scanning unit that scans a sample with a laser beam emitted from a laser light source, and at least one photodetector formed of a superconducting nanowire single photon detector that detects a beam returning from the sample as a result of the scanning of the laser beam by the beam-scanning unit; and
one cryocooler that cools the photodetectors of the laser microscopes.
